(19) United States
(12) Patent Application Publication
(10) Pub. No.: US 2006/0164815 A1
(43) Pub. Date: Jul. 27, 2006

(54) Panel and light shielding device thereof

(75) Inventors: Hung-Chang Chien, Taipei (TW); Ching-Ying Huang, Taipei (TW); Lih-Hwa Kuo, Taipei (TW)

Correspondence Address: BIRCH STEWART KOLASCH & BIRCH, PO BOX 747, FALLS CHURCH, VA, 22040-0747, US

(73) Assignee: Lite-On It Corporation

(21) Appl. No.: 11/339,686

(22) Filed: Jan. 26, 2006

(30) Foreign Application Priority Data
Jan. 27, 2005 (TW) 94102518

(51) Int. Cl. H05K 7/00

(52) U.S. Cl. 361/728

(57) ABSTRACT

A light shielding device disposed in a portable electronic apparatus is provided. The portable electronic apparatus at least including a display panel and a case is disposed in the case. The light shielding device includes an extendable module and a storage module. The extendable module is coupled to the case and shields the ray of light surrounding the display panel when extended. The storage module is disposed in the case for storing the extendable module in the case.

This application claims the benefit of Taiwan Application Serial No. 094102518, filed Jan. 27, 2005, the subject matter of which is incorporated herein by reference.

### BACKGROUND OF THE INVENTION

1. Field of the Invention

The invention relates in general to a light shielding device, and more particularly to a light shielding device of a panel.

2. Description of the Related Art

Conventional portable electronic apparatuses such as digital camera and video recorder are equipped with a display panel for the user to view the recording frame or enter into a select menu. However, when an apparatus is used outdoors, the intensified luminance would incapacitate the user from viewing the contents shown in the display panel clearly.

To resolve the above problem, some manufacturers disposed a viewfinder in the digital video recorder. That is, a channel is formed in the body of the apparatus with a small-sized liquid crystal display (LCD) panel being disposed at the end of the channel, so that the user can view the recorded scene by moving the video recorder to be close to the eyes when the contents of the display panel can not be viewed clearly. However, the installation of a viewfinder, which would incur more cost and cause more inconvenience, still can not resolve the problem that the user can not clearly view the displayed contents under the surroundings of intensified luminance.

### SUMMARY OF THE INVENTION

It is therefore the object of the invention to provide a panel and the light shielding device thereof capable of shielding the ray of light surrounding the panel so as to resolve the problem that the user being unable to view the displayed contents under intensified luminance.

According to an object of the invention, a light shielding device disposed in a portable electronic apparatus is provided. The portable electronic apparatus at least including a case and a display panel which is disposed in the case. The light shielding device includes an extendable module and a storage module. The extendable module is coupled to the case and shields the ray of light surrounding the display panel when extended. The storage module is disposed in the case for storing the extendable module in the case.

According to the object of the invention, another embodiment comprises of a panel disposed in a portable electronic apparatus is provided. The panel including a case, a display panel which is disposed in the case and a light shielding device is disposed in the case. The light shielding device is coupled to the case and capable of blocking the ray of light surrounding the display panel.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a perspective of a light shielding device of a panel according to a first embodiment of the invention when extended;

FIG. 1B is a partial enlarged view of FIG. 1A;

FIG. 1C is a perspective of the light shielding device of FIG. 1A during storage;

FIG. 1D is a perspective of the light shielding device of FIG. 1A after storage;

FIG. 2 is a side view of a bellows of the light shielding device of FIG. 1A;

FIG. 3 is a 3-D diagram of a light shielding device according to a second embodiment of the invention;

FIG. 4 is a 3-D diagram of a panel according to a third embodiment of the invention; and

FIG. 5 is a top view of a ring set of the light shielding device of FIG. 4.

### DETAILED DESCRIPTION OF THE INVENTION

The spirit of the invention is to form a light-shielding mask surrounding the panel, lest the intensified ray of light might be projected onto the panel, incapacitating the user to view the displayed contents clearly. The invention is exemplified by a number of digital video recorders. However, the embodiments disclosed below are only examples of embodiments under the spirit of the invention, and the scope of protection of the invention will not be limited thereto.

### FIRST EMBODIMENT

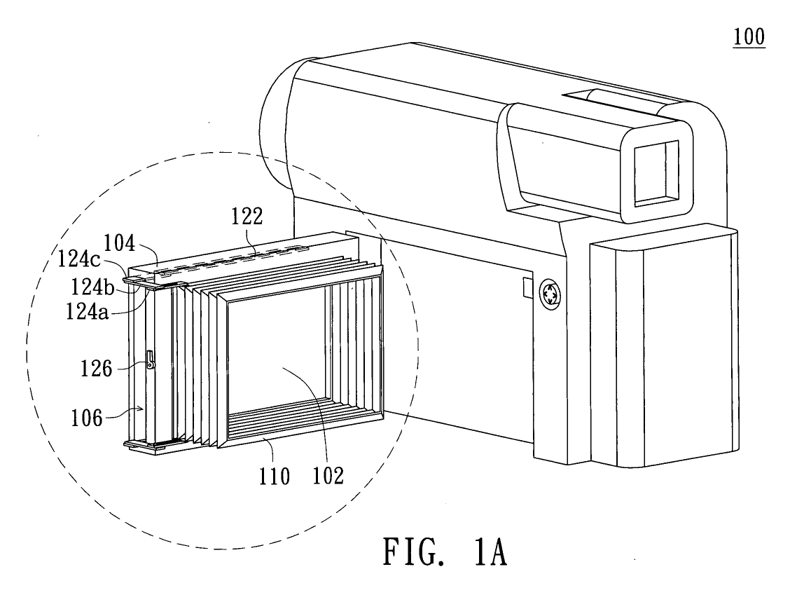

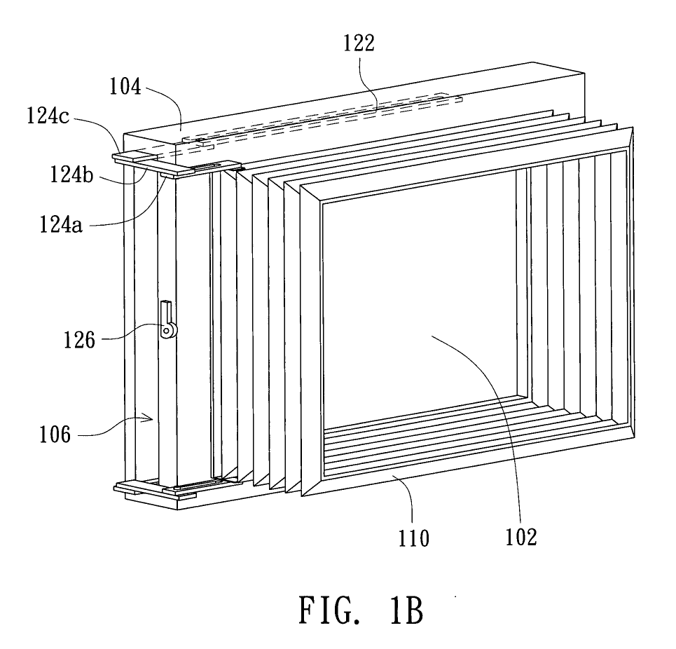

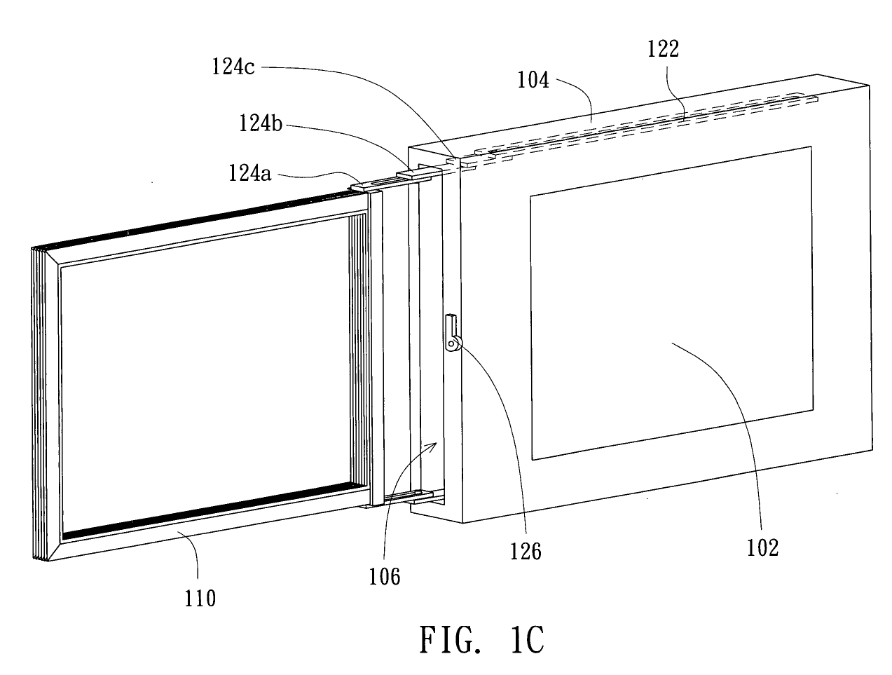

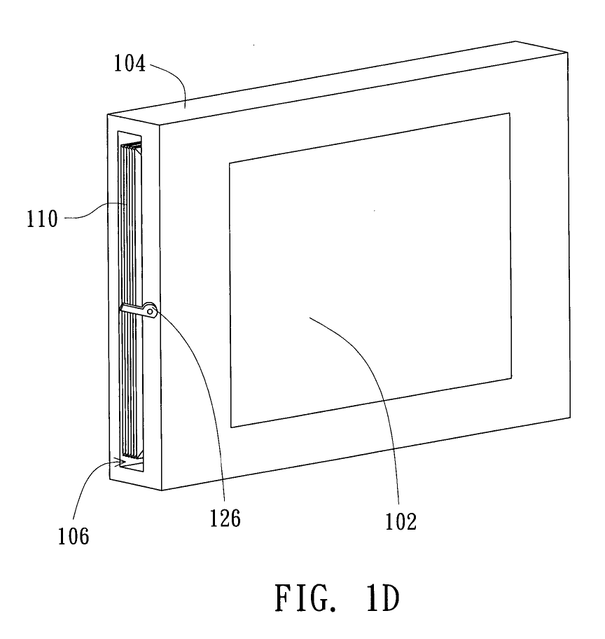

Referring to FIG. 1A, a perspective of a light shielding device of a panel when extended is shown according to a first embodiment of the invention. The panel of the present embodiment is disposed in a portable electronic apparatus such as a video recorder 100 for instance. The panel includes a display panel 102, a case 104 and a light shielding device. The display panel 102 is disposed in the case 104. The light shielding device includes an extendable module and a storage module. The extendable module is a bellows 110 for instance. The bellows 110 is coupled to the case 104, and shields the ray of light surrounding the display panel 102 when extended. The storage module is disposed in the case 104 for receiving the bellows 110 in the case 104.

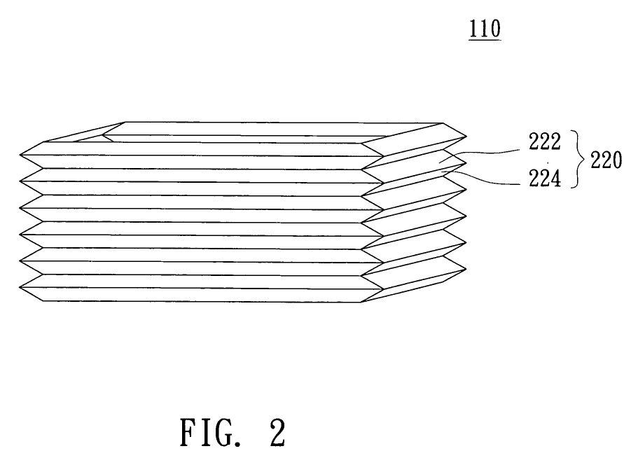

Referring to FIG. 2, a side view of a bellows 110 of the light shielding device of FIG. 1A is shown. Several ring-shaped protrusions 220 are formed on the wall of bellows 110. The ring-shaped protrusions 220 have a common symmetric axis. Each of the ring-shaped protrusions 220 includes an upper cone-shaped structure 222 and a lower cone-shaped structure 224. The lower cone-shaped structure 224 is mounted beneath the upper cone-shaped structure 222. The upper cone-shaped structure 222 overlaps with the lower cone-shaped structure 224 when the bellows 110 is compressed. The upper cone-shaped structure 222 and the lower cone-shaped structure 224 stands side by side on the wall of the bellows 110 when the bellows 110 is extended.

Referring to FIG. 1B, a partially enlarged view of FIG. 1A is shown. The case 104 has a recess 106 for receiving the compressed bellows 110. The recess 106 is positioned at the rear of the display panel 102, and the opening of the recess 106 is positioned at one of the four lateral sides of the case 104.

The storage module restricts the compressed bellows 110 within the recess 106. The storage module includes a slid rod 122, a linking piece and a first fixing component 126. The slid rod 122, which is substantially parallel to the top side of the case 104, is disposed in the recess 106. The linking piece, which is able to crookedly connect the slid rod 122 and the bellows 110, guides the bellows 110 to turn over from the front of the display panel 102 to its lateral side and slide into the recess 106 along the slid rod 122. The linking piece includes a first connecting rod 124a, a second connecting rod 124b and a third connecting rod 124c. The first connecting rod 124a is connected to bellows 110, the second connecting rod 124b is pivotally connected to the first connecting rod 124a, and the third connecting rod 124c is pivotally connected to the second connecting rod 124b and coupled to the slid rod 122. The first fixing component 126 is rotatable and disposed on the wall of the opening of the recess 106. The first fixing component 126 is rotated to be protruded in the opening of the recess 106 for fixing the bellows 110 in the recess 106 when the light shielding device is contracted. The first fixing component 126 can fix the bellows 110 in the recess 106 by a screw or a hook.

As shown in FIG. 1B, when the light shielding device is extended, the first connecting rod 124a, the second connecting rod 124b and the third connecting rod 124c form an inverted U-shaped structure, so that the extended bellows 110 is positioned at the front of the display panel 102 to shield the ray of light. By extending the light shielding device, the user can record the video and view the frame at the same time without being restricted to the small window of viewfinder even under intensified luminance.

Referring to FIG. 1C˜1D at the same time. FIG. 1C is a perspective of the light shielding device of FIG. 1A during storage. FIG. 1D is a perspective of the light shielding device of FIG. 1A after storage. During the storage of the light shielding device, the first connecting rod 124a, the second connecting rod 124b and the third connecting rod 124c form an I-shaped structure. Afterwards, the compressed bellows 110 slides into the recess 106 along the slid rod 122, so that the bellows 110 is received in the case 104. At last, as shown FIG. 1C, the first fixing component 126 is rotated to be protruded in the opening of the recess 106 for fixing the bellows 110 in the recess 106. Once the user is not using the light shielding device, the light shielding device can be completely contracted into the case.

### SECOND EMBODIMENT

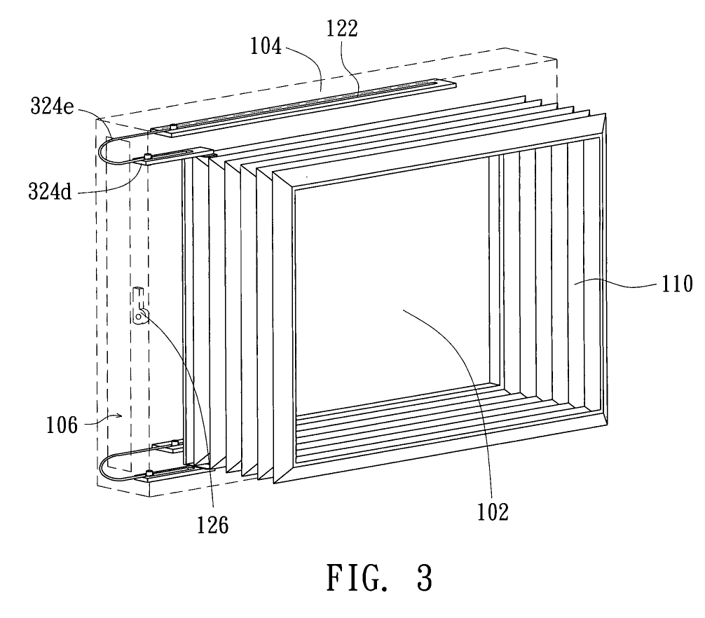

FIG. 3 is a 3-D diagram of a light shielding device according to a second embodiment of the invention. The second embodiment differs from the first embodiment in the storage module of the light shielding device. The difference is that the linking piece includes a fourth connecting rod 324d and an elastic pillar 324e. To avoid repetition of similarities, only the differences between the second embodiment and the first embodiment are disclosed here.

Referring to FIG. 3, the fourth connecting rod 324d is connected to bellows 110. The elastic pillar 324e, made of a bendable material, is pivotally connected to the fourth connecting rod 324d and coupled to the slid rod 122. When the light shielding device is extended, the elastic pillar 324e is bent so that the bellows 110 is positioned at the front of the display panel 102 to shield the ray of light. When the light shielding device is stored up, the elastic pillar 324e forms a straight line structure and slides into the recess 106 along the slid rod 122, so that the bellows 110 is shrunk in the case 104.

### THIRD EMBODIMENT

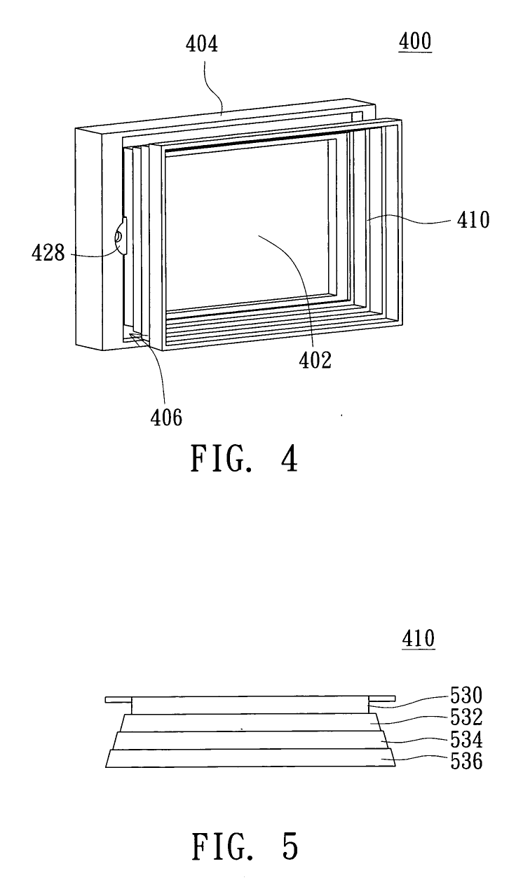

The present embodiment differs from the first embodiment in the position of the recess and the extendable module of the light shielding device. FIG. 4 is a 3-D diagram of a panel according to a third embodiment of the invention. The panel 400 of the present embodiment is disposed in a portable electronic apparatus such as a video recorder or a digital camera for instance. The panel 400 includes a display panel 402, a case 404 and a light shielding device. The display panel 402 is disposed in the case 404. The light shielding device includes an extendable module and a storage module. The extendable module is a ring set 410 for instance. The ring set 410 is coupled to the case 404 and shields the ray of light surrounding the display panel 402 when extended. The storage module is disposed in the case 404 for storing ring set 410 in the case 404.

FIG. 5 is a top view of a ring set 410a of the light shielding device of FIG. 4. The ring set 410 includes four rings having a common symmetric center. The four rings are arranged inside out in the order of rings 530, 532,534 and 536. The inner diameter of the four rings increases from inside out, so that the ring set 410 is able to be compressed properly, and that every ring is mounted inside the immediate outer ring. For example, when ring set 410 is compressed, the ring 536 is mounted outside the ring 534, and the ring 532 is mounted inside the ring 534. Besides, every ring has a front end opening and a rear end opening, the front end opening of every ring is larger than the rear end opening. The inner diameter of the rear end opening of every ring is smaller than the outer diameter of the front end opening of the immediate inner ring, so that the ring set 410 is extended, and the rear end opening of every ring is mounted on the front end opening of the immediate inner ring. For instance, the inner diameter of the rear end opening of the ring 534 is smaller than the outer diameter of the front end opening of the ring 532. When ring set 410 is extended, the rear end opening of the ring 534 is mounted on the front end opening of the adjacent ring 532, thereby several rings are coupled together to form a light-shielding mask.

However, the ring set 410 is not limited to four rings. For instance, the ring set 410 includes N rings having a common symmetric center. The N rings are arranged inside out in the order of a first ring to the N^{th} ring, and the inner diameter of the i^{th} ring is smaller than the inner diameter of the (i+1)^{th} ring. N is a positive integer, and i is a positive integer ranging between 1 and N. When the extendable module is compressed, the (i+1)^{th} ring is mounted outside the i^{th} ring, while the (i−1)^{th} ring is mounted inside the i^{th} ring. Besides, every ring has a front end opening and a rear end opening, the front end opening of every ring is larger than rear end opening, and the inner diameter of the rear end opening of the i^{th} ring is smaller than the outer diameter of front end opening of the (i−1)^{th} ring. When the extendable module is extended, the rear end opening of the i^{th} ring is mounted on the front end opening of the adjacent (i−1)^{th} ring, thereby several rings are coupled together to form a light-shielding mask.

Referring to FIG. 4, the case 404 has the recess 406 for containing ring set 410. The recess 406 is disposed on the front surface of the case 404 and adjacent to the display panel 402. The rear end of the ring set 410 is connected to the inner wall of the recess 406.

The storage module restricts the compressed ring set 410 within the recess 406. The storage module includes a second fixing component rotatably disposed on the wall of the opening of the recess 406. The second fixing component is a cross bar 428 or a hook for instance. As shown in FIG. 4, one end of the cross bar 428 can be pivotally connected to the wall of the opening by a screw for instance, so that another end of the cross bar 428 rotates to be protruded in the opening. By doing so, the cross bar 428 or a hook can fix the ring set 410 in the recess 406.

When the light shielding device is extended, every ring of the ring set 410 is mounted on its adjacent ring, so that the ring set 410 can reduce the ray of light surrounding the display panel 402. When the light shielding device is stored up, every ring of the ring set 410 is positioned inside the immediate outer ring, so that ring set 410 can be compressed. At last, the second fixing component 428 is rotated to be protruded in the opening of the recess 406 to restrict the ring set 410 within the recess 406. By doing so, the light shielding device of the present embodiment can be stored up in the recess or extended to shield the ray of light surrounding the display panel according to user's need, providing further convenience to the user.

The light shielding device disclosed in above embodiment of the invention when extended shields the ray of light surrounding the portable electronic apparatus to resolve the problem that the user can not view the contents displayed in the display panel under the environment of intensified luminance. Therefore, the portable electronic apparatus does not need an extra viewfinder, largely reducing the cost of the portable electronic apparatus. Furthermore, the light shielding device of the invention can be stored up and does not increase the size of the apparatus, so that the portable electronic apparatus still maintain the features of slimness, lightweight and compactness.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light shielding device disposed in a portable electronic apparatus, wherein the portable electronic apparatus comprises a case and a display panel disposed therein, the light shielding device comprising:
an extendable module coupled to the case for shielding a ray of light from the display panel surroundings when being extended; and
a storage module disposed in the case for storing the compressed extendable module in the case.

2. The light shielding device according to claim 1, wherein the extendable module comprises N rings having a common symmetric center arranged inside out in the order of a first ring to an N^{th} ring, the inner diameter of an i^{th} ring being smaller than the inner diameter of a (i+1)^{th} ring, the (i+1)^{th} ring being positioned outside the i^{th} ring and the (i−1)^{th} ring being positioned inside the i^{th} ring when the extendable module is compressed;
wherein N is a positive integer, and i is a positive integer ranging from 1 to N.

3. The light shielding device according to claim 2, wherein each ring has a front end opening and a rear end opening, the front end opening of each ring being larger than the rear end opening, the inner diameter of the rear end opening of the i^{th} ring being smaller than the outer diameter of the front end opening of the (i−1)^{th} ring, when the extendable module is extended, the rear end opening of the i^{th} ring being engaged with the front end opening of the adjacent (i−1)^{th} ring, thereby the rings are coupled together to form a light-shielding mask.

4. The light shielding device according to claim 1, wherein the extendable module is a bellows, a plurality of ring-shaped protrusions having a common symmetric axis formed on the wall of the bellows, each ring-shaped protrusion comprising:
an upper cone-shaped structure; and
a lower cone-shaped structure mounted beneath the upper cone-shaped structure;
wherein the upper cone-shaped structure overlaps with the lower cone-shaped structure when the extendable module is compressed; wherein the upper cone-shaped structure and the lower cone-shaped structure are arranged side by side on the wall of the bellows when the extendable module is extended.

5. The light shielding device according to claim 1, wherein the case has a recess for containing the extendable module, and the storage module restricts the compressed extendable module within the recess.

6. The light shielding device according to claim 5, wherein the recess is positioned at the rear of the display panel and an opening of the recess is positioned at one of the lateral sides of the case.

7. The light shielding device according to claim 6, wherein the storage module comprises:
a slid rod substantially parallel to the top side of the case to be disposed in the recess;
a linking piece bendably connecting the slid rod and the extendable module, the linking piece guiding the extendable module to turn over from the front side of the display panel to its lateral side and slide into the recess along the slid rod; and
a first fixing component rotatably disposed on a wall of the opening of the recess, the first fixing component rotated so as to be protruded in the opening for fixing the extendable module in the recess when the light shielding device is stored up.

8. The light shielding device according to claim 7, wherein the linking piece comprises:
a first connecting rod connected to the extendable module;
a second connecting rod pivotally connected to the first connecting rod;
a third connecting rod, one end of the third connecting rod pivotally connected to the second connecting rod, the other end of the third connecting rod coupled to the slid rod;
wherein when the light shielding device is extended, the first connecting rod, the second connecting rod and the third connecting rod form an inverted U-shaped structure so as to allow the extendable module to be positioned in front of the display panel for shielding the ray of light; wherein when the light shielding device is stored up, the first connecting rod, the second connecting rod and the third connecting rod form an I-shaped structure so as to allow the extendable module to slide into the recess along the slid rod and then be received in the case.

9. The light shielding device according to claim 7, wherein the linking piece comprises:
a fourth connecting rod connected to the extendable module; and
an elastic pillar, made of a bendable material, pivotally connected to the fourth connecting rod and coupled to the slid rod;
wherein when the light shielding device is extended, the elastic pillar is bent so as to allow the extendable module to be positioned in front of the display panel for shield the ray of light; wherein when the light shielding device is stored up, the elastic pillar forms a straight line structure so as to allow the extendable module to slide into the recess along the slid rod and then be received in the case.

10. The light shielding device according to claim 5, wherein the recess is positioned on the front surface of the case and adjacent to the display panel.

11. The light shielding device according to claim 10, wherein a rear end of the extendable module is connected to an inner wall of the recess.

12. The light shielding device according to claim 11, wherein the storage module comprises a second fixing component rotatably disposed on a wall of an opening of the recess, the second fixing component rotated to be protruded in the opening and restricts the extendable module within the recess when the light shielding device is stored up.

13. A panel disposed in a portable electronic apparatus, the panel comprising:
a case;
a display panel disposed in the case; and
a light shielding device coupled to the case for shielding the ray of light from the display panel surroundings.

14. The panel according to claim 13, wherein the case has a recess, and the light shielding device comprises:
an extendable module coupled to the case for shielding a ray of light from the display surroundings when extended, and received in the recess when compressed.

15. The panel according to claim 14, wherein the extendable module comprises N rings having a common symmetric center arranged inside out in the order of a first ring to an N^{th} ring, the inner diameter of a i^{th} ring being smaller than the inner diameter of a (i+1)^{th} ring, the (i+1)^{th} ring being mounted outside the i^{th} ring while the (i−1)^{th} ring being mounted inside the i^{th} ring when the extendable module is compressed;
wherein N is a positive integer, and i is a positive integer ranging form 1 to N.

16. The panel according to claim 15, wherein each ring has a front end opening and a rear end opening, the front end opening of each ring being larger than the rear end opening, and the inner diameter of the rear end opening of the i^{th} ring being smaller than the outer diameter of the front end opening of the (i−1)^{th} ring, the rear end opening of the i^{th} ring engaged with the front end opening of the adjacent (i−1)^{th} ring when the extendable module is extended, thereby the rings are coupled together to form a light-shielding mask.

17. The panel according to claim 14, wherein the extendable module is an bellows, a plurality of ring-shaped protrusion having a common symmetric axis formed on the wall of the bellows, each ring-shaped protrusion comprising:
an upper cone-shaped structure; and
a lower cone-shaped structure mounted beneath the upper cone-shaped structure;
wherein the upper cone-shaped structure overlaps with the lower cone-shaped structure when the extendable module is compressed; wherein the upper cone-shaped structure and the lower cone-shaped structure are arranged side by side on the wall of the bellows when the extendable module is extended.

18. The panel according to claim 14, wherein the recess is positioned at the rear of the display panel, and an opening of the recess is positioned at one of the four lateral sides of the case.

19. The panel according to claim 14, wherein the panel further comprises:
a slid rod substantially parallel to the top side of the case to be disposed in the recess;
a linking piece bendably connecting the slid rod and the extendable module, the linking piece guiding the extendable module to turn over from the front side of the display panel to its lateral side and slide into the recess along the slid rod; and
a first fixing component rotatably disposed on a wall of the opening of the recess, the first fixing component rotated so as to be protruded in the opening for fixing the extendable module in the recess when the light shielding device is stored up.

20. The panel according to claim 19, wherein the linking piece comprises:
a first connecting rod connected to the extendable module;
a second connecting rod pivotally connected to the first connecting rod;
a third connecting rod, one end of the third connecting rod pivotally connected to the second connecting rod, and the other end of the third connecting rod coupled to the slid rod;
wherein when the light shielding device is extended, the first connecting rod, the second connecting rod and the third connecting rod form an inverted U-shaped structure so as to allow the extendable module to be positioned in front of the display panel for shielding the ray of light; wherein when the light shielding device is stored up, the first connecting rod, the second connecting rod and the third connecting rod form an I-shaped structure so as to allow the extendable module to slide into the recess along the slid rod and then be received in the case.

21. The panel according to claim 19, wherein the linking piece comprises:
a fourth connecting rod connected to the extendable module; and
an elastic pillar made of a bendable material, pivotally connected to the fourth connecting rod and coupled to the slid rod;
wherein when the light shielding device is extended, the elastic pillar is bent so as to allow the extendable module to be positioned in front of the display panel for shielding the ray of light; wherein when the light shielding device is stored up, he elastic pillar forms a straight line structure so as to allow the extendable module to slide into the recess along the slid rod and then be received in the case.

22. The panel according to claim 14, wherein the recess is positioned on the front surface of the case and adjacent to the display panel, while a rear end of the extendable module is connected to a inner wall of the recess.

23. The panel according to claim 22, the panel further comprises a second fixing component rotatably disposed on a wall of an opening of the recess, the second fixing component rotated to be protruded in the opening for fixing the extendable module in the recess when the light shielding device is stored up.
